(19) United States
(12) Patent Application Publication
(10) Pub. No.: US 2003/0119295 A1
(43) Pub. Date: Jun. 26, 2003

(54) Wafer and method of fabricating the same

(76) Inventors: Fang-Chu Chang, Chiai (TW); Wen-Bin Yu, Hsinchu (TW); Hsin-Chin Wang, Hsinchu (TW)

Correspondence Address: RABIN & BERDO, P.C., Suite 500, 1101 14th Street, N.W., Washington, DC, 20005, US

(21) Appl. No.: 10/093,047

(22) Filed: Mar. 8, 2002

(30) Foreign Application Priority Data
Dec. 24, 2001 (TW) 90132093

(51) Int. Cl. H01L 21/44

(52) U.S. Cl. 438/612; 438/754

(57) ABSTRACT

A method of manufacturing a wafer is disclosed. The method includes the steps of: (a) providing a substrate on which a number of semiconductor devices are formed and covered with a passivation layer; (b) exposing a number of contact pads in connection with the semiconductor devices by etching a portion of the passivation layer which are corresponding to the contact pads; and (c) cleaning the contact pads by soaking the substrate into a nitric acid solution and than rinsing. The concentration of the nitric acid solution can be about in the range between 0.01 vol. % and 30 vol. % and preferably about in the range between 1 vol. % and 10 vol. %. Thus, defects on wafers are greatly reduced with causing damages.

This application incorporates by reference of Taiwan application Serial No. 90132093, filed Dec. 24, 2001.

### BACKGROUND OF THE INVENTION

1. Field of the Invention

The invention relates in general to a wafer and the fabrication of the wafer, and more particularly to a fabrication method of the wafer by using a nitric acid solution.

2. Description of the Related Art

Integrated circuits (IC) are widely applied in the electrical appliances in people's contemporary lives. ICs are formed by gathering transistors, diodes, resistors, capacitors and other devices on dies. ICs can have the functions of controlling, calculating, or memory.

The yield of the wafer is affected by the defects thereon. In the fabrication of the ICs, due to different conditions of photolithography and etching and different storage environments of the wafer, defects on the contact pads may occur. The detail of the occurrence of defects is described as follows.

1. CF₄ is usually used in the etching process. However, CF₄ may react with the contact pads. For example, AlF₃ could occur on the surface of Aluminum contact pad.

2. Photo-resistor or some other organic solvent may remain in the surface of the contact pad.

3. In the storage environment, chemicals in the air may react with the contact pad so that erosion of the surface of the contact pad may occur.

### SUMMARY OF THE INVENTION

It is therefore an object of the invention to provide an improved method of manufacturing a wafer. The method includes the steps of: (a) providing a substrate on which a number of semiconductor devices are formed and covered with a passivation layer; (b) exposing a number of contact pads in connection with the semiconductor devices by etching a portion of the passivation layer which are corresponding to the contact pads; and (c) cleaning the contact pads by soaking the substrate into a nitric acid solution and than rinsing. The concentration of the nitric acid solution can be about in the range between 0.01 vol. % and 30 vol. % and preferably about in the range between 1 vol. % and 10 vol. %.

It is therefore another object of the invention to provide a wafer, including: a substrate, on which a number of semiconductor devices are formed and a number of contact pads are electrically connected to the semiconductor devices; and a passivation layer covering the semiconductor devices and exposing the contact pads, wherein the contact pads are treated by a nitric acid solution. The concentration of the nitric acid solution can be about in the range between 0.01 vol. % and 30 vol. % and preferably about in the range between 1 vol. % and 10 vol. %.

It is therefore a further object of the invention to provide a new use of a nitric acid solution, wherein the nitric acid solution is used for removing residue on wafers after contact pads are formed thereon; and the nitric acid solution comprises deionized water and nitric acid. The concentration of the nitric acid solution can be about in the range between 0.01 vol. % and 30 vol. % and preferably about in the range between 1 vol. % and 10 vol. %.

Other objects, features, and advantages of the invention will become apparent from the following detailed description of the preferred but non-limiting embodiments. The following description is made with reference to the accompanying drawings.

### BRIEF DESCRIPTION OF THE DRAWINGS

FIGS. 1A to 1C, the fabrication process of the wafer according to a preferred embodiment of the invention is illustrated.

FIG. 2 shows the flow chart of the fabrication process.

### DETAILED DESCRIPTION OF THE INVENTION

The spirit of the invention is to provide a wafer and the method of fabrication the same by using nitric acid solution to wash the wafer, especially the contact pad thereon.

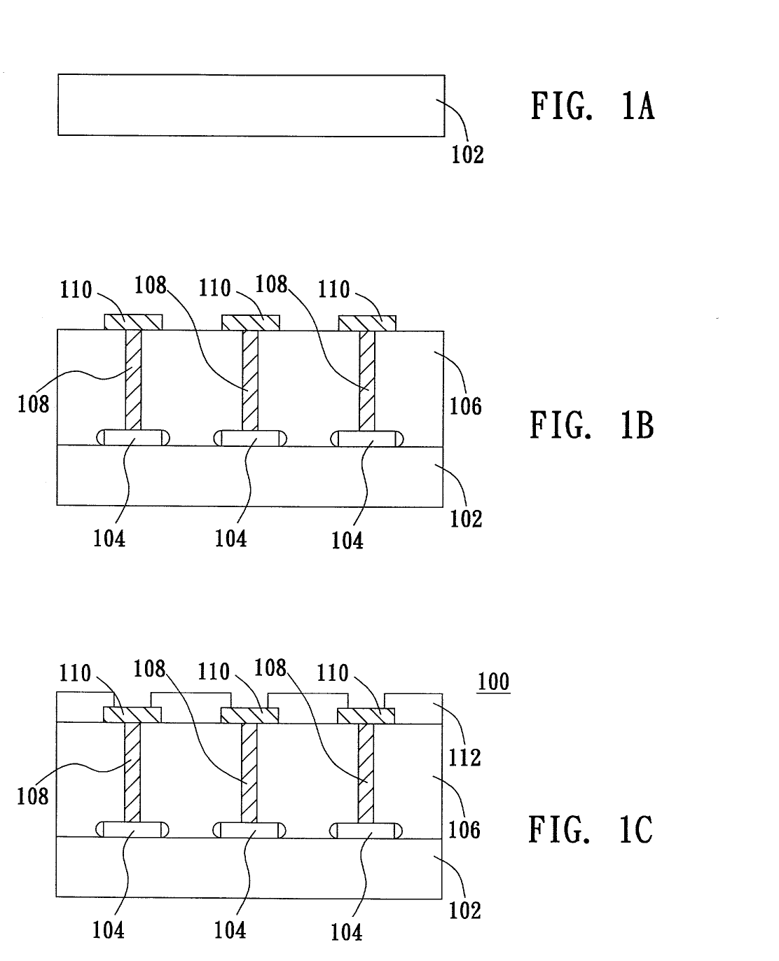

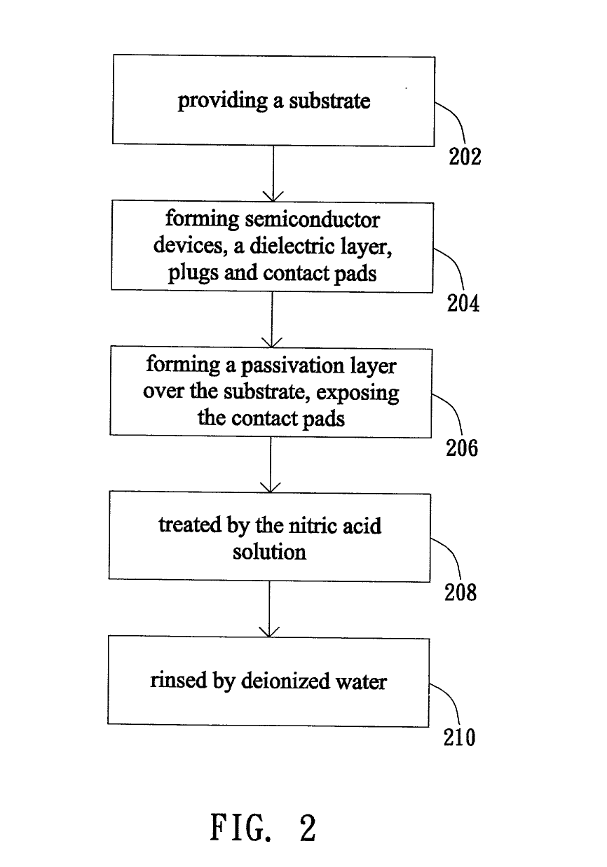

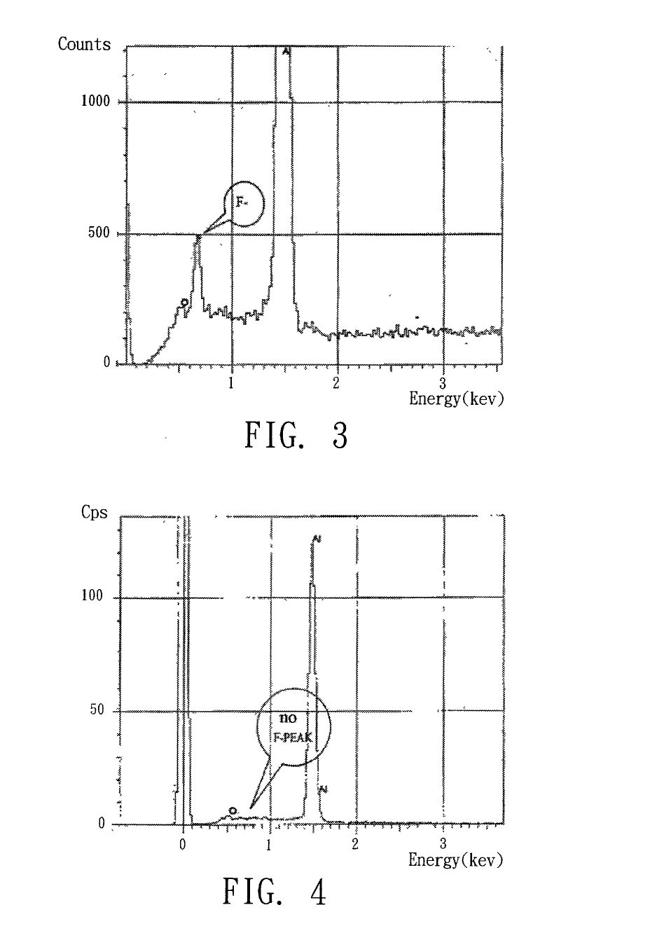

Please referring to FIGS. 1A to 1C, the fabrication process of the wafer according to a preferred embodiment of the invention is illustrated. And please also referring to FIG. 2, the flow chart of the fabrication process is shown.

In FIG. 1A, a substrate 102 is provided. In FIG. 1B, a number of semiconductor devices 104 are formed on the substrate 102. Then, a dielectric layer 106 is formed over the semiconductor devices 104 and a number of plugs 108 are formed through the dielectric layer 106 to contact with the semiconductor devices 104 therebeneath. Contact pads 110 are then formed to be indirectly connected with the semiconductor devices 104 through the plugs 108. The contact pads 110 preferably contain copper or aluminum.

Then, as shown in FIG. 1C and step 206 in FIG. 2, a passivation layer 112 is formed to cover the dielectric layer 106 and contact pads 110. By etching the passivation layer 112 above the contact pads 110, contact pads 110 are exposed for the further processes. Defects on the exposed contact pads 110 could occur. These defects could include photo-resistor residues, AlF₃ and other kinds of erosion.

Steps 208 and 210 in FIG. 2 effectively remove the residue on the contact pad 110. The wafer 100 is soaked in a nitric acid solution. The nitric acid solution slightly etches away the residue on the surface of the contact pads 110 but without damaging the contact pads 110. Then, the wafer 100 is rinsed by deionized water to wash away the nitric acid solution remaining on the contact pads 110 and other surface of the wafer 100.

The formula for the nitric acid solution is a mixture of nitric acid and deionized water. The concentration of the nitric acid solution can be about in the range between 0.01 vol. % and 30 vol. %, preferably in the range between 1 vol. % and 10 vol. %.

To proof that the contact pads are not damaged by the nitric acid solution, the following tests are performed.

1. Wafer sort. Before the wafer is divided into dies, the electrical properties of the wafer are tested. The wafer fabricated according to a preferred embodiment of the invention successfully passes the wafer sort test.

2. Bonding test. This test is to ensure that the wiring can be firmly bonded to the contact pad. The result shows that the wafer fabricated according to a preferred embodiment of the invention have higher rate of firmly bonding than the conventional.

3. Final test. The test is done by testing the electrical properties of the packaged ICs. The result shows that the ICs fabricated according to a preferred embodiment of the invention have higher passing rate than the conventional.

In addition to the above three tests, the dies fabricated according to a preferred embodiment of the invention successfully pass the SAT & F/T test, the package reliability test and the product reliability test.

FIG.3 is the SEM-EDS graph of a wafer with defects. The peak in the graph shows that the amount of fluorine is high. FIG. 4 is the SEM-EDS graph of a wafer fabricated according to a preferred embodiment of the invention. It is shown that the amount of fluorine decreases dramatically.

It is therefore apparent that wafers fabricated according to the invention, treating by nitric acid solution and rising by deionized water, has at least the following advantages: low occurrence of defects, high yield and low cost.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A method of manufacturing a wafer, comprising the steps of:
providing a substrate on which a plurality of semiconductor devices and contact pads are formed and covered with a passivation layer;
exposing the contact pads in connection with the semiconductor devices by etching a portion of the passivation layer which are corresponding to the contact pads; and
cleaning the contact pads by soaking the substrate into a nitric acid solution and than rinsing.

2. The method as claimed in claim 1, wherein the nitric acid solution comprises deionized water and nitric acid.

3. The method as claimed in claim 1, wherein the contact pads are rinses by deionized water.

4. The method as claimed in claim 1, wherein a concentration of the nitric acid solution is about in the range between 0.01 vol. % and 30 vol. %.

5. The method as claimed in claim 1, wherein a concentration of the nitric acid solution is about in the range between 1 vol. % and 10 vol. %.

6. The method as claimed in claim 1, wherein the contact pads comprise copper or aluminum.

7. A wafer, comprising:
a substrate, on which a plurality of semiconductor devices and a plurality of contact pads electrically connected to the semiconductor devices are formed; and
a passivation layer covering the semiconductor devices and exposing the contact pads, wherein the contact pads are treated by a nitric acid solution.

8. The wafer as claimed in claim 7, wherein the nitric acid solution comprises deionized water and nitric acid.

9. The wafer as claimed in claim 7, wherein the contact pads are rinses by deionized water after treated by the nitric acid solution.

10. The wafer as claimed in claim 7, wherein a concentration of the nitric acid solution is about in the range between 0.01 vol. % and 30 vol. %.

11. The wafer as claimed in claim 7, wherein a concentration of the nitric acid solution is about in the range between 1 vol. % and 10 vol. %.

12. A new use of a nitric acid solution for removing residue on contact pads after a passivation layer on a wafer is partially removed so as to expose the contact pads, the nitric acid solution comprising deionized water and nitric acid.

13. The new use of a nitric acid solution as claimed in claim 12, wherein a concentration of the nitric acid solution is about in the range between 0.01 vol. % and 30 vol. %.

14. The new use of a nitric acid solution as claimed in claim 12, wherein a concentration of the nitric acid solution is about in the range between 1 vol. % and 10 vol. %.
